(19) United States
(12) Patent Application Publication
(10) Pub. No.: US 2024/0015892 A1
(43) Pub. Date: Jan. 11, 2024

(54) MANUFACTURING METHOD OF MEMBRANE CIRCUIT BOARD

(71) Applicant: Primax Electronics Ltd., Taipei (TW)

(72) Inventors: Yi-Te Chou, Taipei (TW); Lei-Lung Tsai, Taipei (TW); Chin-Sung Pan, Taipei (TW)

(21) Appl. No.: 17/877,474

(22) Filed: Jul. 29, 2022

(30) Foreign Application Priority Data
Jul. 11, 2022 (TW) 111125987

(51) Int. Cl. H05K 3/12; H05K 3/20; H05K 3/46

(52) U.S. Cl. CPC H05K 3/1216; H05K 3/207; H05K 3/4664; H05K 3/4679; H05K 3/4673

(57) ABSTRACT

A manufacturing method of a membrane circuit board includes the following steps. Firstly, a screen plate, a first substrate body and a second substrate body are provided. Then, a conductive paste and a first circuit pattern are formed on the screen plate. Then, the conductive paste and the first circuit pattern are simultaneously printed on the first substrate body by a screen printing process. The first substrate body, the first circuit pattern and the conductive paste are collaboratively formed as a first membrane substrate. Then, a second circuit pattern is formed on the screen plate. Then, the second circuit pattern is printed on the second substrate body by the screen printing process. The second substrate body and the second circuit pattern are collaboratively formed as a second membrane substrate. Then, the second membrane substrate is aligned with the first membrane substrate.

### FIELD OF THE INVENTION

The present invention relates to an input device, and more particularly to a manufacturing method of a membrane circuit board of a keyboard module.

### BACKGROUND OF THE INVENTION

With increasing development of science and technology, a variety of electronic devices are designed in views of convenience and user-friendliness. For helping the user well operate the electronic devices, the electronic devices are gradually developed in views of humanization. The input devices of the common electronic devices include for example mouse devices, keyboard devices, trackball devices, or the like. Via the keyboard device, texts or symbols can be inputted into the computer system directly. As a consequence, most users and most manufacturers of input devices pay much attention to the development of keyboard devices.

Generally, a keyboard device comprises plural key structures. Each key structure comprises a base plate, a membrane circuit board, a scissors-type connecting member, a keycap and an elastic element. The scissors-type connecting member is connected between the keycap and the base plate. The keycap, the scissors-type connecting member, the elastic element and the membrane circuit board are supported by the base plate. The base plate and the keycap are connected with each other through the scissors-type connecting member. The elastic element is enclosed by the scissors-type connecting member. The membrane circuit board comprises plural key intersections. When one of the key intersections is triggered, a corresponding key signal is generated. The elastic element is disposed on the membrane circuit board. Moreover, each elastic element is aligned with a corresponding key intersection. While the elastic element is pressed down, the elastic element is subjected to deformation, and the corresponding key intersection of the membrane circuit board is pushed by the elastic element. Consequently, the corresponding key intersection is triggered to generate a key signal.

Conventionally, the keys of the keyboard device are arranged in a keyboard matrix. When one keycap is pressed down, a keyboard controller realizes the information of the depressed keycap according to the column information and the row information and outputs the corresponding key signal. Generally, the intersection between each row and each column of the keyboard matrix represents a corresponding key intersection. When one keycap is triggered, the keyboard device starts to scan the keyboard matrix and recognizes which keycap is pressed down. For example, the keyboard controller scans all columns of the keyboard matrix sequentially. If the corresponding signal is received from a specified row when a specified column is scanned by the keyboard controller, the keyboard controller can realize which keycap is pressed down according to the received column information and row information.

The minimum matrix unit of the keyboard matrix is composed of four keys. When any of the four keys is pressed down, the corresponding key signal can be successfully generated. When two of the four keys are arbitrarily pressed down, the keyboard controller can realize which keys are triggered according to the column information and the row information. However, when three keys are simultaneously pressed down, the information of two rows and the information of two columns are transmitted to the keyboard controller. Since four keys are defined by two rows and two columns, the keyboard controller cannot recognize the three depressed keys from the four keys according to the column information and the row information only. Under this circumstance, the fourth key of the four keys is erroneously judged as the on-state key. That is, the fourth key is referred as a ghost key.

For avoiding the ghosting problem, the keyboard device is further equipped with plural diodes near the corresponding key intersections. Since the current is allowed to pass through the membrane switch circuit in one direction through the arrangement of the diodes, the erroneous judgement of the ghosting problem is avoided. However, the approach of installing diodes near the corresponding key intersection still has some drawbacks. Firstly, the diode is not cost-effective. Consequently, the cost of the keyboard device is increased. Secondly, the plural diodes on the membrane switch circuit increase the thickness of the membrane switch circuit. The increased thickness of the membrane switch circuit is detrimental to the slimness of the keyboard device. Thirdly, the process of welding each diode at the position near the corresponding key intersection is very complicated.

Therefore, there is a need of providing an improved manufacturing method of a membrane circuit board in order to overcome the drawbacks of the conventional technologies.

### SUMMARY OF THE INVENTION

An object of the present invention provides a manufacturing method of a membrane circuit board. The manufacturing method is simple, the production yield is increased, and the fabricating cost is reduced.

The other objects and advantages of the present invention will be understood from the disclosed technical features.

In accordance with an aspect of the present invention, a manufacturing method of a membrane circuit board is provided. The manufacturing method includes the following steps. Firstly, a screen plate, a first substrate body and a second substrate body are provided. Then, a conductive paste is formed on the screen plate. Then, a first circuit pattern is formed on the screen plate. Then, the conductive paste and the first circuit pattern are simultaneously printed on the first substrate body by a screen printing process. The conductive paste is connected with the first circuit pattern. Moreover, an equivalent resistance of the conductive paste and the first circuit pattern is formed. The first substrate body, the first circuit pattern and the conductive paste are collaboratively formed as a first membrane substrate. Then, a second circuit pattern is formed on the screen plate. Then, the second circuit pattern is printed on the second substrate body by the screen printing process. The second substrate body and the second circuit pattern are collaboratively formed as a second membrane substrate. Then, the second membrane substrate is aligned with the first membrane substrate.

In an embodiment, before the step of aligning the second membrane substrate with the first membrane substrate, the manufacturing method further includes the following steps. Firstly, a first insulation layer is formed to cover a portion of the first circuit pattern and the conductive paste. Then, a second insulation layer is formed to cover a portion of the second circuit pattern. Then, a waterproof glue layer is formed between the first insulation layer and the second insulation layer.

In an embodiment, the first circuit pattern includes a first contact, and the second circuit pattern includes a second contact. The first contact is exposed through the first insulation layer and the waterproof glue layer. The second contact is exposed through the second insulation layer and the waterproof glue layer. The first contact and the second contact are aligned with each other.

In an embodiment, the conductive paste is connected with the first circuit pattern and located near the first contact.

In an embodiment, the manufacturing method further includes steps of providing an insulation separation substrate and installing the insulation separation substrate between the first membrane substrate and the second membrane substrate.

In an embodiment, the insulation separation substrate further includes at least one opening. The first circuit pattern and the second circuit pattern are electrically connected with each other through the at least one opening.

In an embodiment, the conductive paste is made of high-impedance carbon ink paste.

In an embodiment, the first circuit pattern, the conductive paste and the second circuit pattern are made of silver paste.

In an embodiment, the first substrate body and the second substrate body are made of polyethylene terephthalate (PET), and the membrane circuit board is included in a keyboard module.

From the above descriptions, the present invention provides the manufacturing method of the membrane circuit board. Firstly, the first circuit pattern and the conductive paste made of two different materials are formed on a screen plate. Then, the first circuit pattern and the conductive paste on the screen plate are simultaneously printed on the first substrate body by a screen printing process. Consequently, the adhesive properties of the first circuit pattern and the conductive paste can be effectively increased, and the second baking process can be omitted. The membrane circuit board manufactured by the method of the present invention can prevent from the ghosting problem of the keyboard module. The manufacturing method is simple, the production yield is increased, and the fabricating cost is reduced.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic cross-sectional view illustrating a portion of a membrane circuit board according to an embodiment of the present invention;

FIG. 2 is a flowchart illustrating a manufacturing method of the membrane circuit board as shown in FIG. 1;

FIGS. 3A, 3B and 3C schematically illustrate the steps of simultaneously printing the conductive paste and the first circuit pattern on the first substrate body in the flowchart as shown in FIG. 2;

FIG. 4 is a schematic cross-sectional view illustrating a portion of a membrane circuit board according to an embodiment of the present invention; and

FIG. 5 is a flowchart illustrating a manufacturing method of the membrane circuit board as shown in FIG. 4.

### DETAILED DESCRIPTION OF THE PREFERRED EMBODIMENT

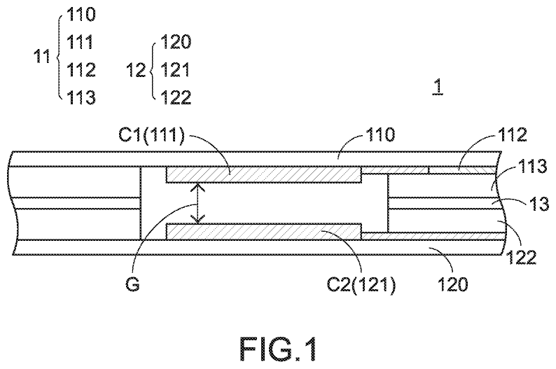

FIG. 1 is a schematic cross-sectional view illustrating a portion of a membrane circuit board according to an embodiment of the present invention. As shown in FIG. 1, the membrane circuit board 1 comprises a first membrane substrate 11, a second membrane substrate 12 and a waterproof glue layer 13.

As shown in FIG. 1, the first membrane substrate 11 comprises a first substrate body 110, a first circuit pattern 111, a conductive paste 112 and a first insulation layer 113. The first circuit pattern 111 is installed on the first substrate body 110. Moreover, the first circuit pattern 111 comprises a first contact C1. The conductive paste 112 is connected with the first circuit pattern 111 and located near the first contact C1. An equivalent resistance of the conductive paste 112 and the first circuit pattern 111 is generated. The adjustment of the equivalent resistance can prevent from the generation of the ghost key. The principle of adjusting the equivalent resistance to avoid the ghosting problem is well known to those skilled in the art, and not redundantly described herein. The first insulation layer 113 covers a portion of the first circuit pattern 111 and the conductive paste 112. The first insulation layer 113 provides the function of insulating the first membrane substrate 11. In this embodiment, the first contact C1 of the first circuit pattern 111 is not covered by the first insulation layer 113. That is, the first contact C1 of the first circuit pattern 111 is exposed through the first insulation layer 113.

As shown in FIG. 1, the second membrane substrate 12 comprises a second substrate body 120, a second circuit pattern 121 and a second insulation layer 122. The second circuit pattern 121 is installed on the second substrate body 120. Moreover, the second circuit pattern 121 comprises a second contact C2. When the second contact C2 of the second circuit pattern 121 is contacted with the first contact C1 of the first circuit pattern 111, a corresponding key signal is generated. The insulation layer 122 covers a portion of the second circuit pattern 121. The second insulation layer 122 provides the function of insulating the second membrane substrate 12. In this embodiment, the second contact C2 of the second circuit pattern 121 is not covered by the second insulation layer 122. That is, the second contact C2 of the second circuit pattern 121 is exposed through the second insulation layer 122.

As shown in FIG. 1, the waterproof glue layer 13 is arranged between the first insulation layer 113 and the second insulation layer 122. The arrangement of the waterproof glue layer 13 can prevent the foreign liquid from contacting with the first circuit pattern 111 or the second circuit pattern 121. That is, the waterproof glue layer 13 provides a waterproof function. In this embodiment, the waterproof glue layer 13 is arranged between the first insulation layer 113 and the second insulation layer 122, but the waterproof glue layer 13 is not aligned with the first contact C1 and the second contact C2. That is, the first contact C1 of the first circuit pattern 111 is exposed through the first insulation layer 113 and the glue layer 13, and the first contact C1 is aligned with the second contact C2. Similarly, the second contact C2 of the second circuit pattern 121 is exposed through the second insulation layer 122 and the glue layer 13, and the second contact C2 is aligned with the first contact C1.

As mentioned above, the first insulation layer 113, the second insulation layer 122 and the glue layer 13 are arranged between the first substrate body 110 and the second substrate body 120. Consequently, there is a gap distance G between the first circuit pattern 111 of the first membrane substrate 11 and the second circuit pattern 121 of the second membrane substrate 12. In this way, the first contact C1 and the second contact C2 are separated from each other.

A manufacturing method of the membrane circuit board 1 will be described in more details as follows.

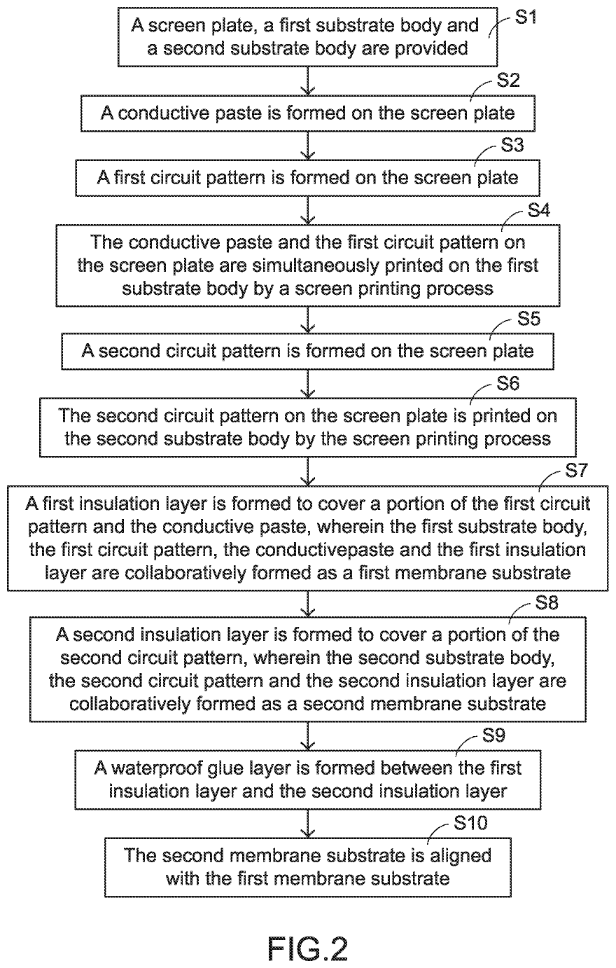

FIG. 2 is a flowchart illustrating a manufacturing method of the membrane circuit board as shown in FIG. 1. Please refer to FIGS. 1 and 2. The manufacturing method of the membrane circuit board 1 comprises the following steps.

Firstly, in a step S1, a screen plate, a first substrate body 110 and a second substrate body 120 are provided.

Then, in a step S2, a conductive paste 112 is formed on the screen plate.

Then, in a step S3, a first circuit pattern 111 is formed on the screen plate.

Then, in a step S4, the conductive paste 112 and the first circuit pattern 111 on the screen plate are simultaneously printed on the first substrate body 110 by a screen printing process. Moreover, the conductive paste 112 is connected with the first circuit pattern 111 and located near the first contact C1. Consequently, an equivalent resistance of the conductive paste 112 and the first circuit pattern 111 is generated.

Then, in a step S5, a second circuit pattern 121 is formed on the screen plate.

Then, in a step S6, the second circuit pattern 121 on the screen plate is printed on the second substrate body 120 by the screen printing process. Moreover, the second contact C2 of the second circuit pattern 121 is aligned with the first contact C1 of the first circuit pattern 111.

Then, in a step S7, a first insulation layer 113 is formed to cover a portion of the first circuit pattern 111 and the conductive paste 112. In this step, the first contact C1 of the first circuit pattern 111 is not covered by the first insulation layer 113. That is, the first contact C1 of the first circuit pattern 111 is exposed through the first insulation layer 113. Moreover, the first substrate body 110, the first circuit pattern 111, the conductive paste 112 and the first insulation layer 113 are collaboratively formed as a first membrane substrate 11.

Then, in a step S8, a second insulation layer 122 is formed to cover a portion of the second circuit pattern 121. In this embodiment, the second contact C2 of the second circuit pattern 121 is not covered by the second insulation layer 122. That is, the second contact C2 of the second circuit pattern 121 is exposed through the second insulation layer 122. Moreover, the second substrate body 120, the second circuit pattern 121 and the second insulation layer 122 are collaboratively formed as a second membrane substrate 12.

Then, in a step S9, a waterproof glue layer 13 is formed between the first insulation layer 113 and the second insulation layer 122.

Then, in a step S10, the second membrane substrate 12 is aligned with the first membrane substrate 11. Particularly, the first contact C1 and the second contact C2 are aligned with each other, and the first contact C1 and the second contact C2 are separated from each other through the first insulation layer 113, the second insulation layer 122 and the glue layer 13.

After the above steps are completed, the first membrane substrate 11 and the second membrane substrate 12 are combined together. Consequently, the membrane circuit board 1 is manufactured.

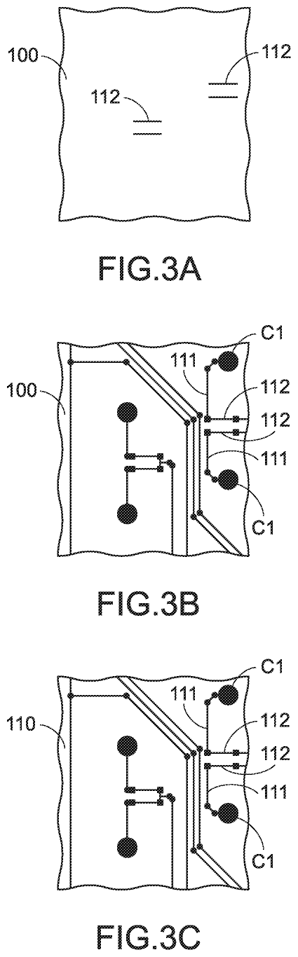

FIGS. 3A, 3B and 3C schematically illustrate the steps of simultaneously printing the conductive paste and the first circuit pattern on the first substrate body in the flowchart as shown in FIG. 2. That is, FIGS. 3A, 3B and 3C illustrate the steps S2, S3 and S4 of the flowchart as shown in FIG. 2. Firstly, as shown in FIG. 3A, the conductive paste 112 is formed on the screen plate 100. Moreover, a circuit pattern formation region is retained on the screen plate 100. Then, as shown in FIG. 3B, the first circuit pattern 111 is formed on the circuit pattern formation region. Consequently, the first circuit pattern 111 is electrically connected with the conductive paste 112, and the conductive paste 112 is located near the first contact C1. Then, as shown in FIG. 3C, the conductive paste 112 and the first circuit pattern 111 on the screen plate 100 are simultaneously printed on the first substrate body 110 by a screen printing process.

Preferably but not exclusively, the first substrate body 110 and the second substrate body 120 are made of polyethylene terephthalate (PET). Preferably but not exclusively, the first insulation layer 113 and the second insulation layer 112 are made of UV-resistant material. Similarly, the first insulation layer 113 and the second insulation 12 can be formed by the screen printing process. Preferably but not exclusively, the first circuit pattern 111 and the second circuit pattern 121 are made of silver paste. In an embodiment, the conductive paste 112 is made of high-impedance carbon ink paste. The material of the conductive paste 112 is not restricted. For example, in another embodiment, the conductive paste 112 is made of silver paste. In case that the first circuit pattern 111, the conductive paste 112 and the second circuit pattern 121 are made of silver paste, the silver content of the conductive paste 112 is lower than the silver content of the first circuit pattern 111 and the silver content of the conductive paste 112. Due to the lower silver content, the conductive paste 112 has the higher impedance value.

In an embodiment, the membrane circuit board 1 is installed in an external keyboard module for a desktop computer (e.g., a PS2 interface keyboard or a USB interface keyboard), or the membrane circuit board 1 is installed in a built-in keyboard module for a notebook computer or a laptop. It is noted that the applications of the membrane circuit board 1 are not restricted. For example, the membrane circuit board 1 can be applied to any other appropriate electronic device that uses the membrane circuit board 1 as a signal input interface.

In case that the membrane circuit board 1 is installed in a keyboard module, the membrane circuit board 1 is located under plural key structures (not shown). Generally, each key structure comprises a base plate, a keycap, a scissors-type connecting member and an elastic element. The relationships between these components are well known to those skilled in the art, and not redundantly described herein. In the membrane circuit board 1, the first circuit pattern 111 of the first membrane substrate 11 comprises plural first contacts C1. The plural first contacts C1 are aligned with the plural key structures, respectively. Moreover, the second circuit pattern 121 of the second membrane substrate 12 of the membrane circuit board 1 comprises plural second contacts C2. The plural second contacts C2 are also aligned with the plural key structures, respectively. When one of the first contacts C1 is contacted with the corresponding second contact C2, a corresponding key signal is generated.

When the keycap of the key structure is not pressed down, the corresponding second contact C2 of the second membrane substrate 12 and the corresponding first contact C1 of the first membrane substrate 11 are separated from each other and not electrically connected with each other. While the keycap is pressed down, the keycap is moved downwardly toward the membrane circuit board 1 to directly or indirectly push the first membrane substrate 11. As the first membrane substrate 11 is pushed, the first membrane substrate 11 is subjected to deformation in the direction toward the second membrane substrate 12, and the first contact C1 of the second membrane substrate 12 is contacted with the second contact C2 of the second membrane substrate 12. Consequently, the depressed key structure is triggered to generate a key signal.

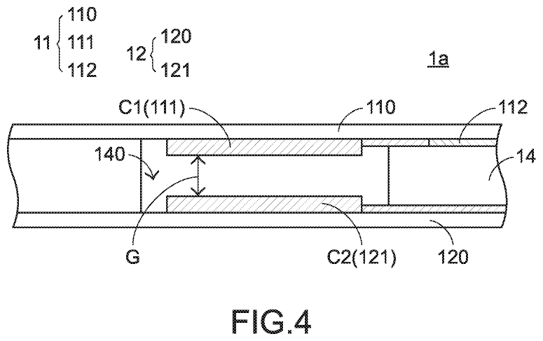

FIG. 4 is a schematic cross-sectional view illustrating a portion of a membrane circuit board according to an embodiment of the present invention. As shown in FIG. 4, the membrane circuit board 1a comprises a first membrane substrate 11, a second membrane substrate 12 and an insulation separation substrate 14.

The first membrane substrate 11 comprises a first substrate body 110, a first circuit pattern 111 and a conductive paste 112. The first circuit pattern 111 is installed on the first substrate body 110. Moreover, the first circuit pattern 111 comprises a first contact C1. The conductive paste 112 is connected with the first circuit pattern 111 and located near the first contact C1. An equivalent resistance of the conductive paste 112 and the first circuit pattern 111 can prevent from the generation of the ghost key.

The second membrane substrate 12 comprises a second substrate body 120 and a second circuit pattern 121. The second circuit pattern 121 is installed on the second substrate body 120. Moreover, the second circuit pattern 121 comprises a second contact C2. When the second contact C2 of the second circuit pattern 121 is contacted with the first contact C1 of the first circuit pattern 111, a corresponding key signal is generated.

The insulation separation substrate 14 is arranged between the first membrane substrate 11 and the second membrane substrate 12. Consequently, there is a gap distance G between the first circuit pattern 111 of the first membrane substrate 11 and the second circuit pattern 121 of the second membrane substrate 12.

Moreover, the insulation separation substrate 14 comprises at least one perforation 140. The perforation 140 is aligned with the first contact C1 of the first circuit pattern 111 and the second contact C2 of the second circuit pattern 121. The first circuit pattern 111 and the second circuit pattern 121 are inserted into the opening 140. Consequently, when the corresponding keycap is pressed down, the first contact C1 and the second contact C2 can be contacted with and electrically connected with each other.

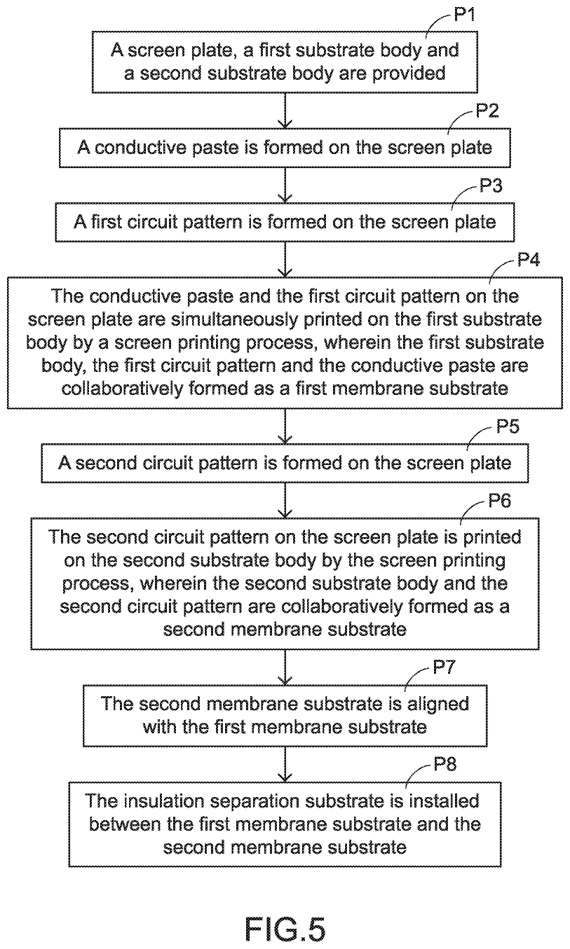

FIG. 5 is a flowchart illustrating a manufacturing method of the membrane circuit board as shown in FIG. 4. Please refer to FIGS. 4 and 5. The manufacturing method of the membrane circuit board 1a comprises the following steps.

Firstly, in a step P1, a screen plate, a first substrate body 110, a second substrate body 120 and an insulation separation substrate 14 are provided.

Then, in a step P2, a conductive paste 112 is formed on the screen plate.

Then, in a step P3, a first circuit pattern 111 is formed on the screen plate.

Then, in a step P4, the conductive paste 112 and the first circuit pattern 111 on the screen plate are simultaneously printed on the first substrate body 110 by a screen printing process. Moreover, the conductive paste 112 is connected with the first circuit pattern 111 and located near the first contact C1. Consequently, an equivalent resistance of the conductive paste 112 and the first circuit pattern 111 is generated. The first substrate body 110, the first circuit pattern 111 and the conductive paste 112 are collaboratively formed as a first membrane substrate 11.

Then, in a step P5, a second circuit pattern 121 is formed on the screen plate.

Then, in a step P6, the second circuit pattern 121 on the screen plate is printed on the second substrate body 120 by the screen printing process. Moreover, the second contact C2 of the second circuit pattern 121 is aligned with the first contact C1 of the first circuit pattern 111. The second substrate body 120 and the second circuit pattern 121 are collaboratively formed as a second membrane substrate 12.

Then, in a step P7, the second membrane substrate 12 is aligned with the first membrane substrate 11. Particularly, the first contact C1 and the second contact C2 are aligned with each other.

Then, in a step P8, the insulation separation substrate 14 is installed between the first membrane substrate 11 and the second membrane substrate 12. The insulation separation substrate 14 has at least one opening 140. The first contact C1 and the second contact C2 are inserted into the opening 140 of the insulation separation substrate 14. In addition, the first contact C1 and the second contact C2 are separated from each other through the insulation separation substrate 14.

After the above steps are completed, the first membrane substrate 11, the insulation separation substrate 14 and the second membrane substrate 12 are combined together. Consequently, the membrane circuit board 1a is manufactured.

The manufacturing method of the present invention can be applied to the two-layered membrane circuit board as shown in FIG. 1 or the third-layered membrane circuit board as shown in FIG. 4. It is noted that applications of the manufacturing method of the present invention are not restricted. For example, in some other embodiments, the manufacturing method of the present invention is applied to a folded-type membrane circuit board or a single-layered membrane circuit board.

From the above descriptions, the present invention provides the manufacturing method of the membrane circuit board. Firstly, the first circuit pattern and the conductive paste made of two different materials are formed on a screen plate. Then, the first circuit pattern and the conductive paste on the screen plate are simultaneously printed on the first substrate body by a screen printing process. Consequently, the adhesive properties of the first circuit pattern and the conductive paste can be effectively increased, and the second baking process can be omitted. The membrane circuit board manufactured by the method of the present invention can prevent from the ghosting problem of the keyboard module. The manufacturing method is simple, the production yield is increased, and the fabricating cost is reduced.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A manufacturing method of a membrane circuit board, the manufacturing method comprising steps of:
providing a screen plate, a first substrate body and a second substrate body;
forming a conductive paste on the screen plate;
forming a first circuit pattern on the screen plate;
simultaneously printing the conductive paste and the first circuit pattern on the first substrate body by a screen printing process, wherein the conductive paste is connected with the first circuit pattern, and an equivalent resistance of the conductive paste and the first circuit pattern is formed, wherein the first substrate body, the first circuit pattern and the conductive paste are collaboratively formed as a first membrane substrate;
forming a second circuit pattern formed on the screen plate;
printing the second circuit pattern on the second substrate body by the screen printing process, wherein the second substrate body and the second circuit pattern are collaboratively formed as a second membrane substrate; and
aligning the second membrane substrate with the first membrane substrate.

2. The manufacturing method according to claim 1, wherein before the step of aligning the second membrane substrate with the first membrane substrate, the manufacturing method further comprises steps of:
forming a first insulation layer to cover a portion of the first circuit pattern and the conductive paste;
forming a second insulation layer to cover a portion of the second circuit pattern; and
forming a waterproof glue layer between the first insulation layer and the second insulation layer.

3. The manufacturing method according to claim 2, wherein the first circuit pattern comprises a first contact, and the second circuit pattern comprises a second contact, wherein the first contact is exposed through the first insulation layer and the waterproof glue layer, the second contact is exposed through the second insulation layer and the waterproof glue layer, and the first contact and the second contact are aligned with each other.

4. The manufacturing method according to claim 3, wherein the conductive paste is connected with the first circuit pattern and located near the first contact.

5. The manufacturing method according to claim 1, further comprising steps of:
providing an insulation separation substrate; and
installing the insulation separation substrate between the first membrane substrate and the second membrane substrate.

6. The manufacturing method according to claim 5, wherein the insulation separation substrate further comprises at least one opening, wherein the first circuit pattern and the second circuit pattern are electrically connected with each other through the at least one opening.

7. The manufacturing method according to claim 1, wherein the conductive paste is made of high-impedance carbon ink paste.

8. The manufacturing method according to claim 1, wherein the first circuit pattern, the conductive paste and the second circuit pattern are made of silver paste.

9. The manufacturing method according to claim 1, wherein the first substrate body and the second substrate body are made of polyethylene terephthalate (PET), and the membrane circuit board is included in a keyboard module.
